(19) United States
(12) Patent Application Publication
(10) Pub. No.: US 2026/0121406 A1
(43) Pub. Date: Apr. 30, 2026

(54) ON-CHIP VOLTAGE PREDICTION CIRCUIT BASED ON PARAMETERS OF POWER DELIVERY NETWORK

(71) Applicant: SOUTHEAST UNIVERSITY, Nanjing (CN)

(72) Inventors: Weiwei SHAN, Nanjing (CN); Kaize ZHOU, Nanjing (CN); Xin SI, Nanjing (CN); Zhe JIANG, Nanjing (CN); Longxing SHI, Nanjing (CN); Jun YANG, Nanjing (CN)

(73) Assignee: SOUTHEAST UNIVERSITY, Nanjing (CN)

(21) Appl. No.: 19/478,284

(22) PCT Filed: Oct. 18, 2024
(86) PCT No.: PCT/CN2024/125746

§ 371 Date: Oct. 24, 2025

(30) Foreign Application Priority Data
Feb. 7, 2024 (CN) 202410173431.1

(51) Int. Cl. H02J 3/0014; G01R 19/25

(52) U.S. Cl. CPC H02J 3/0014; G01R 19/2503

(57) ABSTRACT

The provided is an on-chip voltage prediction circuit based on parameters of the chip's power delivery network. The circuit includes: an on-chip PDN impedance scanning module, an on-chip voltage monitoring module, an on-chip PDN parameter lookup table storage module, an on-chip predictive digital power meter, and an on-chip voltage prediction-calculation module. The circuit establishes a physical model that maps historical voltages and predicted current information to predicted voltage information. By quantizing the model and using the voltage monitoring circuit and the predictive digital power meter together, the provided implements on-chip deployment of the voltage prediction circuit, and effectively predicts future on-chip voltages.

### TECHNICAL FIELD

This application discloses an on-chip voltage prediction circuit based on parameters of the chip's power delivery network, and relates to the technical field of calculation, derivation, or counting, and in particular, to a low-power-consumption design technology for integrated circuits.

### BACKGROUND TECHNOLOGY

With the rapid development of integrated circuits, chip fabrication processes and integration levels have been continuously improving, and the rate of current change on a chip has been increasing, thereby leading to on-chip voltage fluctuations. In the case of severe voltage fluctuations, a timing margin of a circuit will be insufficient or even fail to meet the minimum voltage requirement, thereby resulting in circuit malfunction. The frequency of voltage fluctuations ranges from tens to hundreds of megahertz. The highest frequency of voltage fluctuations depends on magnitudes of a package inductance and an on-chip capacitance in the power delivery network (PDN). To cope with voltage fluctuations, the on-chip voltage needs to be regulated by using a low-dropout linear regulator, a DC-DC converter, or other means, so as to avoid timing errors. However, as a prerequisite of voltage regulation, on-chip voltage data needs to be obtained in real time to determine the direction of voltage regulation.

Due to the influence of a synchronous clock, an on-chip voltage monitoring module contains a post-processing circuit, a calibration circuit, and other circuits, thereby resulting in a delay between an output code value and the on-chip voltage. Although an on-chip predictive digital power meter can predict dynamic power consumption in advance, power consumption changes are unable to be directly mapped to on-chip voltage fluctuations. Conventional on-chip voltage prediction schemes incur some problems. For example, voltage prediction based on a microarchitecture of processors relies on human-derived experience to select events, thereby making it difficult for the schemes to adapt to different application scenarios. The implementation of the designs based on a historical voltage and a support vector machine requires a large number of multiply-accumulate units, and the circuit scale limits the prediction accuracy. Schemes based on historical voltages and a voltage variation slope can hardly perform accurate prediction on complex voltage changes due to limited monitoring windows.

Therefore, there is a need for a voltage prediction circuit based on a physical model of the chip's power delivery network. The voltage prediction circuit enables prediction of on-chip voltage with reference to in-chip historical voltage information and predicted power consumption information, so as to implement accurate prediction of complex and varying on-chip voltages by using low hardware overhead.

### CONTENT OF THE INVENTION

An objective of this application is to overcome the disadvantages of existing technologies and disclose an on-chip voltage prediction circuit based on the chip's power delivery network. Through on-chip voltage monitoring, on-chip power prediction, on-chip voltage prediction-calculation and other technologies, this application solves the problems of high hardware cost and low prediction accuracy of existing voltage prediction circuits.

To achieve the above objective, this application puts forward the following technical solutions.

An on-chip voltage prediction circuit based on parameters of the chip's power delivery network, including: an on-chip PDN impedance scanning module, an on-chip PDN parameter lookup table storage module, an on-chip voltage monitoring module, an on-chip predictive digital power meter, and an on-chip voltage prediction-calculation module. The on-chip PDN impedance scanning module is configured to apply currents of different frequencies on a chip to obtain a PDN impedance-frequency curve. The on-chip voltage monitoring module is configured to monitor and record on-chip voltages in real time, obtain on-chip voltages corresponding to periodical variations of the currents, and output historical voltage code values. The on-chip PDN parameter lookup table storage module is configured to store on-chip PDN parameters obtained based on the on-chip voltages at the currents of different frequencies and a PDN impedance-frequency curve. The on-chip predictive digital power meter is configured to monitor an on-chip current in real time and output a predicted current code value. The on-chip voltage prediction-calculation module is configured to receive the historical voltage code values output by the on-chip voltage monitoring module and the predicted current code value output by the on-chip predictive digital power meter, substitute the received historical voltage code values and the predicted current code value into an on-chip voltage prediction formula V_{dp}[n]=c1*I_{d}[n]+c2*I_{d}[n−1]+c3*I_{d}[n−2]−d1*V_{dn}[n−1]−d2*V_{dn}[n−2] obtained by quantizing the on-chip PDN parameters, and calculate a predicted voltage code value of a digital system based on the on-chip voltage prediction formula.

As an optimized scheme of the on-chip voltage prediction circuit based on parameters of the chip's power delivery network, the on-chip PDN parameters are obtained by a host computer based on the on-chip voltages at the currents of different frequencies and the PDN impedance-frequency curve, and specifically, the host computer derives an effective value of the on-chip voltages at the currents of different frequencies and calculates an impedance value of the PDN at different frequencies, fits a second-order impedance network transfer function formula that matches the PDN impedance-frequency curve, and extracts parameters in the second-order impedance network transfer function formula as the on-chip PDN parameters.

As a further optimized scheme of the on-chip voltage prediction circuit based on parameters of the chip's power delivery network, a specific method for the host computer to derive the effective value of the on-chip voltages at the currents of different frequencies and calculate the impedance value of the PDN at different frequencies is: for an on-chip voltage U(f) at a frequency f a half of a difference between a maximum value and a minimum value of the on-chip voltage U(f) at the frequency f is divided by a square root of 2 to obtain the effective value of the on-chip voltage at the frequency f, and the effective value of the on-chip voltage at the frequency f is divided by an effective value of a current at the frequency f to obtain the impedance value of the PDN at the frequency f.

As a further optimized scheme of the on-chip voltage prediction circuit based on parameters of the chip's power delivery network, the fitting a second-order impedance network transfer function formula that matches the PDN impedance-frequency curve is specifically: transforming the second-order impedance network transfer function formula

$$Z ( s ) = \frac{a 1 * s + a 2}{{s}^{2} + b 1 * s + b 2}$$

that matches the PDN impedance-frequency curve based on a Laplace frequency transformation relationship to obtain a correspondence formula between impedance and frequency, and then fitting the second-order impedance network transfer function formula to each data point on the PDN impedance-frequency curve by use of a least square method to obtain parameters a1, a2, b1, and b2.

As a further optimized scheme of the on-chip voltage prediction circuit based on parameters of the chip's power delivery network, the on-chip voltage prediction formula obtained by quantizing the on-chip PDN parameters is V_{dp}[n]=c1*I_{d}[n]+c2*I_{d}[n−1]+c3*I_{d}[n−2]−d1*V_{dn}[n−1]−d2*V_{dn}[n−2], where V_{dp}[n] is a predicted voltage value at a time point n, I_{d}[n] is a predicted current value at the time point n, I_{d}[n−1] is a predicted current value at a time point n−1, I_{d}[n−2] is a predicted current value at a time point n−2, V_{dn}[n−1] is a detected on-chip voltage value at the time point n−1, and V_{dn}[n−2] is a detected on-chip voltage value at the time point n−2; c1, c2, c3, d1, and d2 are parameters of a transfer function obtained by transforming a second-order impedance network transfer function formula into a discrete z-domain based on a bilinear transformation formula

$$s = \frac{2}{T} * \frac{z - 1}{z + 1} \cdot c 1 = \frac{2 a 1 T + a 2 {T}^{2}}{b 2 {T}^{2} + 2 b 1 T + 4} , \\ c 2 = \frac{2 a 2 {T}^{2}}{b 2 {T}^{2} + 2 b 1 T + 4} , c 3 = \frac{a 2 {T}^{2} - 2 a 1 T}{b 2 {T}^{2} + 2 b 1 T + 4} , \\ d 1 = \frac{2 b 2 {T}^{2} - 8}{b 2 {T}^{2} + 2 b 1 T + 4} , and d 2 = \frac{b 2 {T}^{2} - 2 b 1 T + 4}{b 2 {T}^{2} + 2 b 1 T + 4} ,$$

and T is one system clock period. The corresponding parameters c1, c2, c3, d1, and d1 of the power delivery network are multiplied by the predicted current value I_{d}[n] at the time point n, the predicted current value I_{d}[n−1] at the time point n−1, the predicted current value I_{d}[n−2] at the time point n−2, the detected on-chip voltage value V_{dn}[n−1] at the time point n−1, and the detected on-chip voltage value V_{dn}[n−2] at the time point n−2, respectively, through multipliers. Subsequently, the resulting products are summed and subtracted through a three-stage adder to output a predicted on-chip voltage value V_{dp}[n] at the time point n. The delays of the discrete sequences are implemented with D flip-flops clocked by the system clock. With reference to the outputs of the on-chip voltage monitoring module and the on-chip predictive digital power meter, the disclosed on-chip voltage prediction circuit based on parameters of the chip's power delivery network can obtain a predicted voltage code value.

As a further optimized scheme for the on-chip voltage prediction circuit based on parameters of the chip's power delivery network, the on-chip PDN impedance scanning module includes: a configuration module and an artificial current load module. The configuration module is configured to control the turn-on of each ring oscillator circuit in the artificial current load module. The artificial current load module includes a user-definable number of ring oscillator circuits, and is configured to simulate currents of different frequencies on a load as controlled by the configuration module.

As a further optimized scheme of the on-chip voltage prediction circuit based on parameters of the chip's power delivery network, the on-chip voltage monitoring module includes: a voltage-controlled oscillator, a code value sampling module, and a quantization logic module. The voltage-controlled oscillator is configured to map variations of on-chip voltages to variations of a device delay. The code value sampling module is configured to sample signal flip positions on a voltage-controlled oscillator. The quantization logic module is configured to count the signal flip positions on the voltage-controlled oscillator at a beginning of a sampling period, the signal flip positions on the voltage-controlled oscillator at an end of the sampling period, and a total number of oscillation cycles within one system clock period T, and output historical voltage code values.

As a further optimized scheme of the on-chip voltage prediction circuit based on parameters of the chip's power delivery network, the on-chip predictive digital power meter includes: a signal flip monitoring module, a current calculation module, and a current correction module. The signal flip monitoring module is deployed in each processor system and configured to monitor a flip state of a key signal in a pertinent processor system and output a flip monitoring result of the key signal in the pertinent processor system to the current calculation module in the pertinent processor system. The current calculation module is deployed in each processor system and configured to multiply the flip monitoring result of the key signal in the pertinent processor system by a corresponding weight through a multiplier to obtain a current corresponding to a flip of each key signal, and sum currents corresponding to flips of all key signals by use of an adder tree to obtain a current value corresponding to the flip of the key signal on the pertinent processor system. The current correction module is configured to add the current value corresponding to the flip of the key signal in each processor system and a current value on a clock tree to obtain a current of each processor, and sum currents of processors with active clocks to obtain a predicted current code value.

The above technical solutions of this application exhibit at least the following advantages:

(1) The on-chip voltage prediction circuit disclosed in this application uses an on-chip PDN impedance scanning module and works together with a host computer to obtain PDN parameters through fitting. The variations of the currents at different frequencies and the voltage are monitored by using a fully integrated circuit, so as to obtain a true power delivery network impedance, which is simple and easy to implement. The chip impedance parameters can be obtained by just running the on-chip PDN impedance scanning module once before the chip is shipped from the factory. Subsequently, the PDN impedance scanning module may be turned off during running of the chip, without generating additional power consumption.

(2) This application implements on-chip voltage prediction based on parameters of the chip's power delivery network. Compared with the conventional voltage monitoring scheme, this application can predict the on-chip voltage in real time, thereby avoiding monitoring hysteresis. In addition, this application allows for the characteristics of the power delivery network of the chip, so that the obtained prediction result is more real and reliable than the prediction performed based solely on the detected voltage value during operation.

(3) This application uses a physical model to derive a real-time on-chip voltage, and implements hardware with reference to the predicted current and the detected on-chip voltage by using a transfer network formula. Compared with other voltage prediction schemes, this application reduces hardware overhead, and improves accuracy of prediction with the model.

### DESCRIPTION OF THE DRAWINGS

FIG. 1 is a schematic diagram of an on-chip voltage prediction circuit based on parameters of the chip's power delivery network according to this application;

FIG. 2 is a schematic diagram of a physical model of an on-chip power delivery network according to this application;

FIG. 3 is a schematic diagram of an on-chip PDN impedance scanning module according to this application;

FIG. 4 is a schematic diagram of an on-chip voltage monitoring module according to this application;

FIG. 5 is a schematic diagram of an on-chip predictive digital power meter according to this application;

FIG. 6 is a circuit diagram of an on-chip voltage prediction-calculation module according to this application; and

FIG. 7 is a simulation effect diagram of on-chip voltage prediction according to this application.

### SPECIFIC IMPLEMENTATIONS

In order to enable better understanding of the objective, structure, and functions of this application, the following describes an on-chip voltage prediction circuit based on parameters of the chip's power delivery network in this application in more detail with reference to the accompanying drawings.

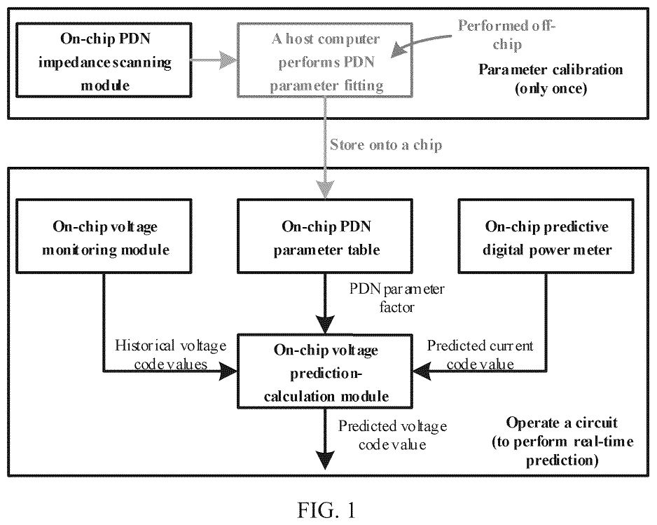

FIG. 1 shows an on-chip voltage prediction circuit based on parameters of the chip's power delivery network. The on-chip voltage prediction circuit includes: an on-chip PDN impedance scanning module, an on-chip PDN parameter lookup table storage module, an on-chip voltage monitoring module, an on-chip predictive digital power meter, and an on-chip voltage prediction-calculation module. The on-chip PDN impedance scanning module is configured to apply currents of different frequencies on a chip to obtain a PDN impedance-frequency curve. The on-chip voltage monitoring module is configured to monitor and record on-chip voltages at the currents of different frequencies in real time, obtain on-chip voltages corresponding to periodical variations of the currents, and output historical voltage code values. The on-chip PDN parameter lookup table storage module is configured to store on-chip PDN parameters obtained based on the on-chip voltages at the currents of different frequencies and a PDN impedance-frequency curve. The on-chip predictive digital power meter is configured to monitor an on-chip current in real time and output a predicted current code value. The on-chip voltage prediction-calculation module is configured to receive the historical voltage code values output by the on-chip voltage monitoring module and the predicted current code value output by the on-chip predictive digital power meter, substitute the received historical voltage code values and the predicted current code value into an on-chip voltage prediction formula obtained by quantizing the on-chip PDN parameters, and calculate a predicted voltage code value of a digital system based on the on-chip voltage prediction formula. The on-chip PDN parameters are obtained by a host computer based on the on-chip voltages at the currents of different frequencies and a PDN impedance-frequency curve.

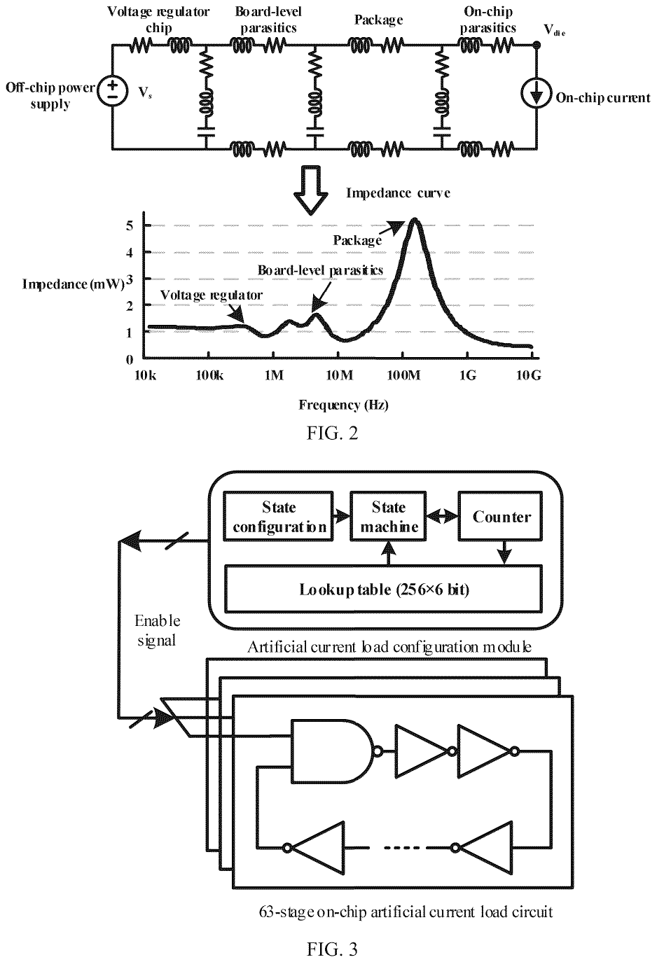

FIG. 2 is a schematic diagram of a physical model of an on-chip power delivery network. The upper part of FIG. 2 shows parasitic impedances encountered when an off-chip power supply is transmitted to different physical locations, where a regulated power supply typically adopts a switching power supply architecture, and an output end of the regulated power supply includes an inductor and a filter capacitor. From the regulated power supply to the power input of the chip, the power generally travels through a relatively long routing trace. To ensure that the power supplied to the chip is not adversely affected, a decoupling capacitor is typically disposed on a PCB board near the chip to prevent voltage fluctuations. During chip packaging, parasitic inductance and resistance are introduced by bonding wires and chip pins of the package. In addition, the parasitic capacitance introduced by on-chip devices and the on-chip decoupling capacitance are also non-negligible. The lower part of FIG. 2 shows a frequency characteristic curve of a PDN impedance of a typical processor. The impedance peak is exhibited at a frequency of approximately 100 MHz, and is primarily caused by the parasitic inductance of the package, the on-chip parasitic capacitance, and the decoupling capacitance. The voltage droop caused by this peak impedance is generally a maximum possible voltage droop on the chip, and a sufficient margin needs to be reserved at the chip design stage to accommodate this worst-case voltage droop. The s-domain second-order impedance network model transfer function of the power delivery network represented by this curve is

$$Z ( s ) = \frac{a 1 * s + a 2}{{s}^{2} + b 1 * s + b 2} .$$

A host computer transforms the second-order impedance network transfer function formula

$$Z ( s ) = \frac{a 1 * s + a 2}{{s}^{2} + b 1 * s + b 2}$$

that matches the PDN impedance-frequency curve based on a Laplace frequency transformation relationship to obtain a correspondence formula between impedance and frequency, and then fits the PDN impedance-frequency curve to each data point by use of the least square method to obtain parameters a1, a2, b1, and b2 of the second-order impedance network transfer function formula. Subsequently, the on-chip voltage prediction-calculation module may transform the s-domain second-order impedance network transfer function formula into a discrete z-domain transfer function based on the bilinear transformation formula:

$$s = \frac{2}{T} * \frac{z - 1}{z + 1} ,$$

where T in the bilinear transformation formula is a clock period of a digital circuit system:

$$Z ( s ) = \frac{c 1 + c 2 * {z}^{- 1} + c 3 * {z}^{- 2}}{1 + d 1 * {z}^{- 1} + d 2 * {z}^{- 2}} .$$

The on-chip PDN impedance scanning module simulates the currents of different frequencies on the load by use of a user-definable number of ring oscillator circuits on the chip by configuring the number of turned-on ring oscillators in different cycles. FIG. 3 is a schematic diagram of an on-chip PDN impedance scanning module. This module includes a configuration module and an M-stage artificial current load module. Each stage of the artificial current load module includes N inverters connected in a ring to 1 NAND gate, where N+1 is any odd number greater than 32. Another input end of the NAND gate serves as an enable signal. When the enable signal is 1, the artificial current load oscillates to generate a current load of a fixed magnitude. When the enable signal is 0, the ring oscillator is disabled to stop producing a current. By controlling the enable signal at each time point, different current magnitudes can be generated at different time points. The configuration module performs state configuration and includes a state machine, a counter, and a lookup table. First, a complete period of a sine signal with an amplitude of 0 to M is sampled at X evenly spaced points, and stored in the lookup table. The data in the lookup table is read at intervals of p points based on a configuration signal, to change the oscillation frequency of the configured current. Finally, the state machine and the counter determine the position of data in the lookup table, where the data corresponds to an enable signal output at the current time point. After being decoded, the enable signal corresponds to the number of turned-on artificial current loads of magnitudes of 0 to M.

The host computer derives an effective value of the voltage based on the on-chip voltage value at the currents of different frequencies recorded by the on-chip voltage monitoring module. The calculation formula of the effective value Ur(f) of the on-chip voltage at the frequency f is

$$Ur ( f ) = \frac{Um ( f )}{\sqrt{2}} ,$$

where Um(f) is a half of the maximum value and the minimum value of the on-chip voltage at the detected frequency

$$f : Um ( f ) = \frac{max ( U ( f ) ) - min ( U ( f ) )}{2} .$$

The effective value of the on-chip voltage at the frequency f is divided by the effective value of the current at the frequency f to obtain a specific impedance of the power delivery network at the configured frequency f. The host computer transforms the s-domain second-order impedance network transfer function Z(s) of the power delivery network based on the Laplace frequency transformation relationship to obtain a correspondence formula between impedance and frequency, and fits the s-domain second-order impedance network model transfer function formula of the power delivery network by use of the least square method based on each data point (Zk, fk) on the impedance-frequency curve obtained through PDN scanning, so as to obtain the parameters a1, a2, b1, and b2, where s represents a Laplacian operator, Zk represents the impedance at the k^{th} data point on the impedance-frequency curve, and fk represents the frequency at the k^{th} data point on the impedance-frequency curve.

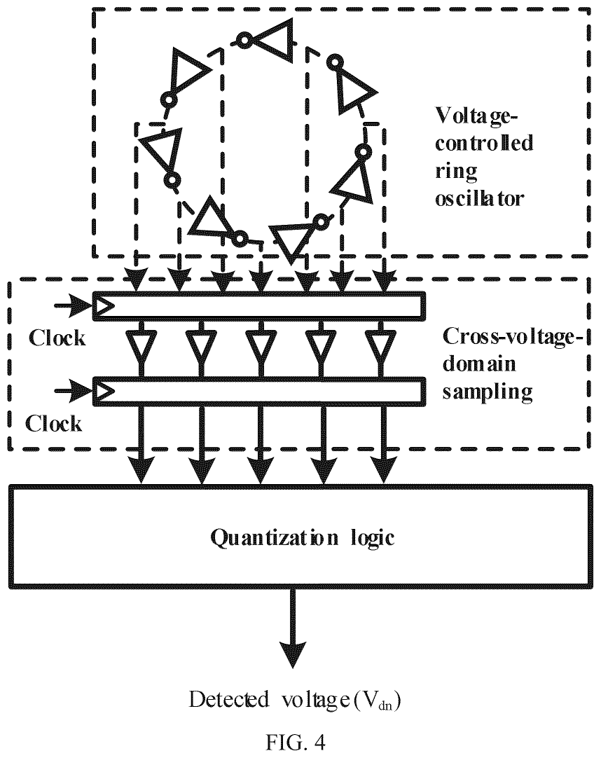

FIG. 4 is a schematic diagram of an on-chip voltage monitoring module. This module primarily includes a voltage-controlled ring oscillator, a cross-voltage-domain sampling module, and a quantization logic module. The finally output detected voltage code value, V_{dn}, represents the quantized voltage value at the current time point. First, the voltage-controlled ring oscillator maps variations of the voltage to variations of a device delay. The cross-voltage-domain sampling module samples the flip positions of the ring oscillator, and then the quantization logic module counts the signal flip positions at the beginning of a sampling period, the signal flip positions at the end of the sampling period, the total number of oscillation cycles within one sampling period T, and ultimately outputs a voltage code value, V_{dn}.

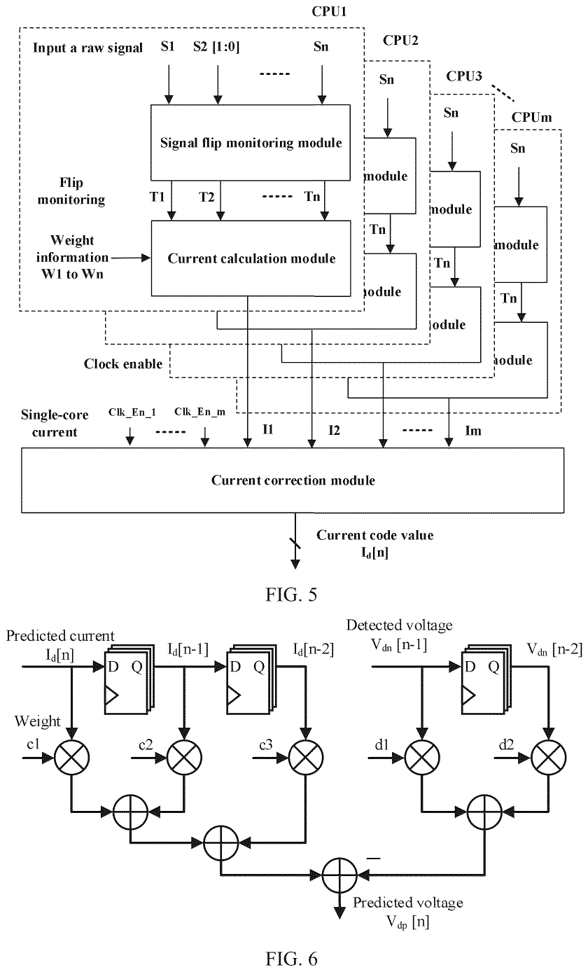

FIG. 5 is a schematic diagram of a predictive digital power meter module. The predictive digital power meter module circuit includes three parts: a signal flip monitoring module, a current calculation module, and a current correction module. For a multi-core digital system chip, each processor is configured with a signal flip monitoring module and a current calculation module. The signal flip monitoring module determines whether an input raw signal has flipped, and denotes the signal flip monitoring result as 1 or 0; and for a multi-bit signal, performs an OR operation on each signal flip monitoring result to determine whether the signal as a whole has flipped. The current calculation module multiplies the signal flip monitoring result by a corresponding weight by using a multiplier, and then sums the currents corresponding to all signal flips by use of an adder tree to obtain a current value corresponding to the signal flip on a single processor. The current correction module adds the current corresponding to the signal flip on each processor in a multi-core digital system and the current on a clock tree to obtain the current of each processor, determines whether the clock of the corresponding processor is valid, and finally sums the currents of all processors to obtain an entire-system dynamic current code value the multi-core digital system chip. The weight information in the current calculation module is obtained by training a feature network. The network is trained to obtain a weight that enables a network output result to reflect the power consumption value of the digital system, and the network is trained by the flip states of specified key signals in the digital chip system as a network input and using the corresponding system power consumption value as a network label.

FIG. 6 is a circuit diagram of an on-chip voltage prediction-calculation module. A scanning module obtains the chip's power delivery network curve, and fits the curve to obtain parameters

$$c 1 = \frac{2 a 1 T + a 2 {T}^{2}}{b 2 {T}^{2} + 2 b 1 T + 4} , c 2 = \frac{2 a 2 {T}^{2}}{b 2 {T}^{2} + 2 b 1 T + 4} , c 3 = \frac{a 2 {T}^{2} - 2 a 1 T}{b 2 {T}^{2} + 2 b 1 T + 4} , \\ d 1 = \frac{2 b 2 {T}^{2} - 8}{b 2 {T}^{2} + 2 b 1 T + 4} , and d 2 = \frac{b 2 {T}^{2} - 2 b 1 T + 4}{b 2 {T}^{2} + 2 b 1 T + 4}$$

in a z-domain transfer function, and then performs an inverse Z-transformation on the z-domain transfer function to obtain a discrete sequence equation suitable for circuit implementation, that is, obtain an on-chip voltage prediction formula by quantizing on-chip PDN parameters:

$${V}_{dp} [ n ] = c 1 * {I}_{d} [ n ] + c 2 * {I}_{d} [ n - 1 ] + c 3 * {I}_{d} [ n - 2 ] - d 1 * {V}_{dn} [ n - 1 ] - d 2 * {V}_{dn} [ n - 2 ] .$$

In the formula above, I_{d}[n] corresponds to a predicted current value at a time point n, which is an output of the predictive digital power meter; and V_{dn}[n−1] corresponds to the detected on-chip voltage value at the time point n−1, which is an output of the voltage monitoring module. First, the corresponding parameters c1, c2, c3, d1, d2 of the power delivery network are multiplied by the predicted current value I_{d}[n] at the time point n, the predicted current value I_{d}[n−1] at the time point n−1, the predicted current value I_{d}[n−2] at the time point n−2, the detected on-chip voltage value V_{dn}[n−1] at the time point n−1, and the detected on-chip voltage value V_{dn}[n−2] at the time point n−2, respectively, through multipliers. Subsequently, the resulting products are summed or subtracted through a three-stage adder to obtain a predicted on-chip voltage value V_{dp}[n] at the time point n. The delays of the discrete sequences are implemented with D flip-flops clocked by the system clock.

Due to the quantization delay of the voltage monitoring module, the calculation lags behind the real-time voltage value. Therefore, this formula predicts the real-time voltage V_{dp}[n] by use of the measured values Id[n], Id[n−1], Id[n−2], V_{dn}[n−1], and V_{dn}[n−2] with reference to parameters of the power delivery network.

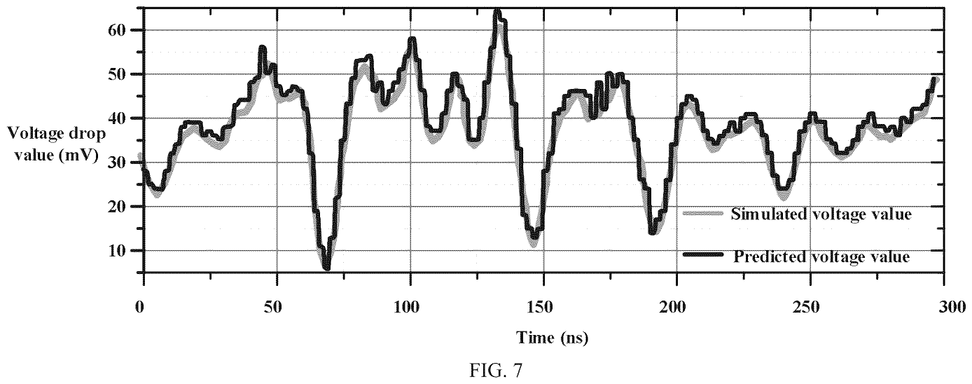

FIG. 7 is a simulation effect diagram of voltage prediction. In the figure, the horizontal axis represents time in nanoseconds, and the vertical axis represents the voltage droop value, calculated by subtracting the actual on-chip voltage from the output voltage of the off-chip regulated power supply. The gray line in the figure represents the voltage drop value in a simulated waveform, and the black line represents the voltage drop value predicted by the voltage prediction circuit of this application. As can be seen, the trends of the two lines are quite consistent, with the maximum prediction error being less than 5 mV.

Understandably, this application is described with reference to some embodiments. A person skilled in the art may make various changes or equivalent substitutions to the features and embodiments without departing from the essence and scope of this application. In addition, based on the teachings of this application, the features and embodiments may be modified to adapt to specific circumstances without departing from the essence and scope of this application. Therefore, this application is not limited to the specific embodiments disclosed herein, and all embodiments falling within the scope of the claims hereof are covered by the scope of protection of this application.

What is claimed is:

1. An on-chip voltage prediction circuit based on parameters of a chip's power delivery network, comprising:
an on-chip PDN impedance scanning module, configured to apply currents of different frequencies on a chip to obtain a PDN impedance-frequency curve;
an on-chip voltage monitoring module, configured to monitor and record on-chip voltages at the currents of different frequencies in real time, obtain on-chip voltages corresponding to periodical variations of the currents, and output historical voltage code values;
an on-chip PDN parameter lookup table storage module, configured to store on-chip PDN parameters obtained based on the on-chip voltages at the currents of different frequencies and a PDN impedance-frequency curve;
an on-chip predictive digital power meter, configured to monitor an on-chip current in real time and output a predicted current code value; and
an on-chip voltage prediction-calculation module, configured to receive the historical voltage code values output by the on-chip voltage monitoring module and the predicted current code value output by the on-chip predictive digital power meter, substitute the received historical voltage code values and the predicted current code value into an on-chip voltage prediction formula obtained by quantizing the on-chip PDN parameters, and calculate and output an on-chip voltage predicted code value.

2. The on-chip voltage prediction circuit based on the parameters of the chip's power delivery network according to claim 1, wherein the on-chip PDN parameters are obtained by a host computer based on the on-chip voltages at the currents of different frequencies and the PDN impedance-frequency curve, and specifically, the host computer derives an effective value of the on-chip voltages at the currents of different frequencies and calculates an impedance value of PDN at different frequencies, fits a second-order impedance network transfer function formula that matches the PDN impedance-frequency curve, and extracts parameters in the second-order impedance network transfer function formula as the on-chip PDN parameters.

3. The on-chip voltage prediction circuit based on the parameters of the chip's power delivery network according to claim 2, wherein a specific method for the host computer to derive the effective value of the on-chip voltages at the currents of different frequencies and calculates the impedance value of the PDN at different frequencies is: for an on-chip voltage U(f) at a frequency f, a half of a difference between a maximum value and a minimum value of the on-chip voltage U(f) at the frequency f is divided by a square root of 2 to obtain the effective value of the on-chip voltage at the frequency f, and the effective value of the on-chip voltage at the frequency f is divided by an effective value of a current at the frequency f to obtain the impedance value of the PDN at the frequency f.

4. The on-chip voltage prediction circuit based on the parameters of the chip's power delivery network according to claim 3, wherein the fitting the second-order impedance network transfer function formula that matches the PDN impedance-frequency curve is specifically: transforming the second-order impedance network transfer function formula
$$Z ( s ) = \frac{a 1 * s + a 2}{{s}^{2} + b 1 * s + b 2}$$
that matches the PDN impedance-frequency curve based on a Laplace frequency transformation relationship to obtain a correspondence formula between impedance and frequency, and then fitting the second-order impedance network transfer function formula to each data point on the PDN impedance-frequency curve by use of a least square method to obtain parameters a1, a2, b1, and b2.

5. The on-chip voltage prediction circuit based on the parameters of the chip's power delivery network according to claim 1, wherein the on-chip voltage prediction formula obtained by quantizing the on-chip PDN parameters is V_{dp}[n]=c1*I_{d}[n]+c2*I_{d}[n−1]+c3*I_{d}[n−2]−d1*V_{dn}[n−1]−d2*V_{dn}[n−2], wherein V_{dp}[n] is a predicted voltage value at a time point n, I_{d}[n] is a predicted current value at the time point n, I_{d}[n−1] is a predicted current value at a time point n−1, I_{d}[n−2] is a predicted current value at a time point n−2, V_{dn}[n−1] is a detected on-chip voltage value at the time point n−1, and V_{dn}[n−2] is a detected on-chip voltage value at the time point n−2; c1, c2, c3, d1, and d2 are parameters of a transfer function obtained by transforming a second-order impedance network transfer function formula into a discrete z-domain based on a bilinear transformation formula
$$s = \frac{2}{T} * \frac{z - 1}{z + 1} ; c 1 = \frac{2 a 1 T + a 2 {T}^{2}}{b 2 {T}^{2} + 2 b 1 T + 4} , \\ c 2 = \frac{2 a 2 {T}^{2}}{b 2 {T}^{2} + 2 b 1 T + 4} , c 3 = \frac{a 2 {T}^{2} - 2 a 1 T}{b 2 {T}^{2} + 2 b 1 T + 4} , \\ d 1 = \frac{2 b 2 {T}^{2} - 8}{b 2 {T}^{2} + 2 b 1 T + 4} , and d 2 = \frac{b 2 {T}^{2} - 2 b 1 T + 4}{b 2 {T}^{2} + 2 b 1 T + 4} ,$$
wherein T is one system clock period.

6. The on-chip voltage prediction circuit based on the parameters of the chip's power delivery network according to claim 1, wherein the on-chip PDN impedance scanning module comprises:
a configuration module, configured to control turn-on of each ring oscillator circuit in an artificial current load module; and
the artificial current load module, comprising a user-definable number of ring oscillator circuits, and configured to simulate currents of different frequencies on a load as controlled by the configuration module.

7. The on-chip voltage prediction circuit based on the parameters of the chip's power delivery network according to claim 1, wherein the on-chip voltage monitoring module comprises:
a voltage-controlled oscillator, configured to map variations of the on-chip voltages at the currents of different frequencies to variations of a device delay;
a code value sampling module, configured to sample signal flip positions on a voltage-controlled oscillator; and
a quantization logic module, configured to count the signal flip positions on the voltage-controlled oscillator at a beginning of a sampling period, the signal flip positions on the voltage-controlled oscillator at an end of the sampling period, and a total number of oscillation cycles within one system clock period T, and output historical voltage code values.

8. The on-chip voltage prediction circuit based on the parameters of the chip's power delivery network according to claim 1, wherein the on-chip predictive digital power meter comprises:
a signal flip monitoring module deployed in each processor system and configured to monitor a flip state of a key signal in a pertinent processor system and output a flip monitoring result of the key signal in the pertinent processor system to a current calculation module in the pertinent processor system;
the current calculation module deployed in each processor system and configured to multiply the flip monitoring result of the key signal in the pertinent processor system by a corresponding weight through a multiplier to obtain a current corresponding to a flip of each key signal, and sum currents corresponding to flips of all key signals by use of an adder tree to obtain a current value corresponding to the flip of the key signal on the pertinent processor system; and
a current correction module, configured to add the current value corresponding to the flip of the key signal in each processor system and a current value on a clock tree to obtain a current of each processor, and sum currents of processors with active clocks to obtain a predicted current code value.

9. The on-chip voltage prediction circuit based on the parameters of the chip's power delivery network according to claim 2, wherein the on-chip voltage prediction formula obtained by quantizing the on-chip PDN parameters is V_{dp}[n]=c1*I_{d}[n]+c2*I_{d}[n−1]+c3*I_{d}[n−2]−d1*V_{dn}[n−1]−d2*V_{dn}[n−2], wherein V_{dp}[n] is a predicted voltage value at a time point n, I_{d}[n] is a predicted current value at the time point n, I_{d}[n−1] is a predicted current value at a time point n−1, I_{d}[n−2] is a predicted current value at a time point n−2, V_{dn}[n−1] is a detected on-chip voltage value at the time point n−1, and V_{dn}[n−2] is a detected on-chip voltage value at the time point n−2; c1, c2, c3, d1, and d2 are parameters of a transfer function obtained by transforming a second-order impedance network transfer function formula into a discrete z-domain based on a bilinear transformation formula
$$s = \frac{2}{T} * \frac{z - 1}{z + 1} ; c 1 = \frac{2 a 1 T + a 2 {T}^{2}}{b 2 {T}^{2} + 2 b 1 T + 4} , \\ c 2 = \frac{2 a 2 {T}^{2}}{b 2 {T}^{2} + 2 b 1 T + 4} , c 3 = \frac{a 2 {T}^{2} - 2 a 1 T}{b 2 {T}^{2} + 2 b 1 T + 4} , \\ d 1 = \frac{2 b 2 {T}^{2} - 8}{b 2 {T}^{2} + 2 b 1 T + 4} , and d 2 = \frac{b 2 {T}^{2} - 2 b 1 T + 4}{b 2 {T}^{2} + 2 b 1 T + 4} ,$$
wherein T is one system clock period.

10. The on-chip voltage prediction circuit based on the parameters of the chip's power delivery network according to claim 3, wherein the on-chip voltage prediction formula obtained by quantizing the on-chip PDN parameters is V_{dp}[n]=c1*I_{d}[n]+c2*I_{d}[n−1]+c3*I_{d}[n−2]−d1*V_{dn}[n−1]−d2*V_{dn}[n−2], wherein V_{dp}[n] is a predicted voltage value at a time point n, I_{d}[n] is a predicted current value at the time point n, I_{d}[n−1] is a predicted current value at a time point n−1, I_{d}[n−2] is a predicted current value at a time point n−2, V_{dn}[n−1] is a detected on-chip voltage value at the time point n−1, and V_{dn}[n−2] is a detected on-chip voltage value at the time point n−2; c1, c2, c3, d1, and d2 are parameters of a transfer function obtained by transforming a second-order impedance network transfer function formula into a discrete z-domain based on a bilinear transformation formula
$$s = \frac{2}{T} * \frac{z - 1}{z + 1} ; c 1 = \frac{2 a 1 T + a 2 {T}^{2}}{b 2 {T}^{2} + 2 b 1 T + 4} , \\ c 2 = \frac{2 a 2 {T}^{2}}{b 2 {T}^{2} + 2 b 1 T + 4} , c 3 = \frac{a 2 {T}^{2} - 2 a 1 T}{b 2 {T}^{2} + 2 b 1 T + 4} , \\ d 1 = \frac{2 b 2 {T}^{2} - 8}{b 2 {T}^{2} + 2 b 1 T + 4} , and d 2 = \frac{b 2 {T}^{2} - 2 b 1 T + 4}{b 2 {T}^{2} + 2 b 1 T + 4} ,$$
wherein T is one system clock period.

11. The on-chip voltage prediction circuit based on the parameters of the chip's power delivery network according to claim 4, wherein the on-chip voltage prediction formula obtained by quantizing the on-chip PDN parameters is V_{dp}[n]=c1*I_{d}[n]+c2*I_{d}[n−1]+c3*I_{d}[n−2]−d1*V_{dn}[n−1]−d2*V_{dn}[n−2], wherein V_{dp}[n] is a predicted voltage value at a time point n, I_{d}[n] is a predicted current value at the time point n, IA[n−1] is a predicted current value at a time point n−1, I_{d}[n−2] is a predicted current value at a time point n−2, V_{dn}[n−1] is a detected on-chip voltage value at the time point n−1, and V_{dn}[n−2] is a detected on-chip voltage value at the time point n−2; c1, c2, c3, d1, and d2 are parameters of a transfer function obtained by transforming a second-order impedance network transfer function
$$s = \frac{2}{T} * \frac{z - 1}{z + 1} ; c 1 = \frac{2 a 1 T + a 2 {T}^{2}}{b 2 {T}^{2} + 2 b 1 T + 4} , \\ c 2 = \frac{2 a 2 {T}^{2}}{b 2 {T}^{2} + 2 b 1 T + 4} , c 3 = \frac{a 2 {T}^{2} - 2 a 1 T}{b 2 {T}^{2} + 2 b 1 T + 4} , \\ d 1 = \frac{2 b 2 {T}^{2} - 8}{b 2 {T}^{2} + 2 b 1 T + 4} , and d 2 = \frac{b 2 {T}^{2} - 2 b 1 T + 4}{b 2 {T}^{2} + 2 b 1 T + 4} ,$$
wherein T is one system clock period.
